(19) United States
(12) Patent Application Publication
(10) Pub. No.: US 2025/0220840 A1
(43) Pub. Date: Jul. 3, 2025

(54) WIRELESS ADAPTER

(71) Applicant: CHENG UEI PRECISION INDUSTRY CO., LTD., New Taipei City (TW)

(72) Inventor: CHIN-CHUNG LIN, New Taipei City (TW)

(21) Appl. No.: 18/827,842

(22) Filed: Sep. 8, 2024

(30) Foreign Application Priority Data
Dec. 27, 2023 (CN) 202323596877.5

(51) Int. Cl. H05K 5/00; H01H 13/04; H01R 13/516

(52) U.S. Cl. CPC H05K 5/10; H01H 13/04; H01R 13/516

(57) ABSTRACT

A wireless adapter includes a housing, an adapter unit, a connector and a push button structure. A front end of the housing defines a connecting hole penetrating through a front surface of the housing. The adapter unit is mounted in the housing. The adapter unit includes a switch unit mounted on a top surface of the adapter unit. The connector is fastened to a front end of the adapter unit. The connector is electrically connected to the adapter unit. The connector is disposed in the housing. A front end of the connector projects out of the connecting hole of the housing. The push button structure is mounted in the housing.

### CROSS REFERENCE TO RELATED APPLICATIONS

The present application is based on, and claims priority from, China Patent Application No. 202323596877.5, filed Dec. 27, 2023, the disclosure of which is hereby incorporated by reference herein in its entirety.

### BACKGROUND OF THE INVENTION

### Field of the Invention

The present invention generally relates to a wireless adapter, and more particularly to a portable wireless adapter which has simple assembling procedures and improves a stability of a push button structure.

### Description of Related Art

Generally, an electronic product, such as a wireless mouse or a wireless keyboard transmits signals to a computer host by a wireless adapter which is inserted to the computer host. The wireless adapter is usually provided with a push button for controlling a working status of the wireless adapter.

With the trend of making the electronic products lighter, thinner and smaller, various electronic components used in the electronic products are also lighter, thinner and smaller, so that the electronic products save spaces to be portable. The various electronic components include a push button. Commonly, the push button on the market has a flexible arm. The push button is assembled in a housing of the electronic product, and then one end of the flexible arm is fastened to the housing by a hot fusion way, so that the push button is assembled completely. In that case, after the push button is pressed, the push button is released, the push button rebounds to an original position of the push button by an elastic force of the flexible arm. Nevertheless, the push button is assembled more complicatedly by the hot fusion way, and the push button takes more time to be assembled by the hot fusion way. In addition, a length of the flexible arm of the push button is relatively longer, so the push button occupies a relatively larger space inside the housing. As a result, the electronic components are hardly developed towards a trend of making the electronic components lighter, thinner and smaller.

A wireless adapter includes a housing, a printed circuit board mounted in the housing, and an elastic element. A top surface of the housing has a button area. The printed circuit board is equipped with a switching element. The elastic element is made of an elastic material. The elastic element is disposed above the switching element of the printed circuit board, a stroke gap between the elastic element and the switching element, the button area of the housing is pressed against the elastic element. When a user presses the button area, the elastic element is pressed to be deformed, and the elastic element presses against the switching element on the printed circuit board to trigger an electric signal. After the user releases the button area, the switching element is restored to an original position of the switching element by an elastic deformation of the elastic element.

However, in this structural design, after the elastic element is repeatedly pressed for a long time, the elastic element is prone to cause an elastic fatigue, consequently, after the user releases the button area, the elastic element has no way of returning to an original position of the elastic element immediately, the elastic element is unable to effectively trigger the switching element on the printed circuit board. As a result, a stability of the triggered electric signal is affected.

Therefore, it is necessary to provide a portable wireless adapter which has simple assembling procedures and improves a stability of a push button structure.

### BRIEF SUMMARY OF THE INVENTION

An object of the present invention is to provide a portable wireless adapter which has simple assembling procedures and improves a stability of a push button structure. The wireless adapter includes a housing, an adapter unit, a connector and a push button structure. A front end of the housing defines a connecting hole penetrating through a front surface of the housing. One side of a top of the housing defines a penetrating hole vertically penetrating through the top of the housing. One side of an inner surface of the top of the housing protrudes downward to form a pivoting section. The pivoting section has a pivoting hole penetrating through a front surface of the pivoting section. The adapter unit is mounted in the housing. The adapter unit includes a switch unit mounted on a top surface of the adapter unit. The connector is fastened to a front end of the adapter unit. The connector is electrically connected to the adapter unit. The connector is disposed in the housing. A front end of the connector projects out of the connecting hole of the housing. The push button structure is mounted in the housing. The push button structure has an assembling end which has a pivoting shaft extending longitudinally, a moving end movably disposed in the penetrating hole, and a connecting arm connected between the assembling end and the moving end. The pivoting shaft is rotatably inserted into the pivoting hole. The moving end has a triggering element. The triggering element is disposed corresponding to the switch unit of the adapter unit for triggering the switch unit.

Another object of the present invention is to provide a wireless adapter. The wireless adapter includes a main shell, a push button structure, an adapter unit, a lid and a connector. The main shell has a rear wall, and a peripheral wall extended frontward form a periphery of the rear wall. A front end of the peripheral wall defines a mounting hole communicated between an inside of the main shell and an outside. One side of an inner surface of a top of the peripheral wall protrudes downward to form a pivoting section. An inside of the pivoting section has a pivoting hole penetrating through a front surface of the pivoting section. An opening of the pivoting hole is corresponding to the mounting hole. One side of the top of the peripheral wall defines a penetrating hole vertically penetrating through the top of the peripheral wall. The push button structure is assembled into the main shell through the mounting hole. The push button structure has a push button, a retaining flange extended outward and downward from a periphery of the push button, a pivoting shaft extending longitudinally, a triggering element protruded downward from a bottom surface of the push button and connected with two inner side surfaces of the retaining flange, and a connecting arm. The pivoting shaft is disposed opposite to the retaining flange. The pivoting shaft is rotatably inserted into the pivoting hole through the opening of the pivoting hole. The push button is movably disposed in the penetrating hole. The retaining flange abuts against the inner surface of the top of the peripheral wall of the main shell, and a bottom wall of the penetrating hole is blocked by the retaining flange. A middle of the connecting arm is a U shape. Two free sides of the connecting arm are transversely protruded oppositely from two sides of a top of the middle of the connecting arm. The two free sides of the connecting arm are connected to the pivoting shaft and the retaining flange. The adapter unit is assembled into the main shell through the mounting hole. The adapter unit includes a switch unit mounted on a top surface of the adapter unit. The triggering element is disposed corresponding to the switch unit. The lid seals the mounting hole. A middle of a front wall of the lid defines a connecting hole longitudinally penetrating through the front wall of the lid. The connector is fastened to a front end of the adapter unit. The connector is electrically connected to the adapter unit. The connector is mounted in the main shell. A front end of the connector projects out of the connecting hole.

Another object of the present invention is to provide a wireless adapter. The wireless adapter includes a main shell having a peripheral wall, a front end of the peripheral wall defining a mounting hole communicated between an inside of the main shell and an outside, one side of an inner surface of a top of the peripheral wall protruding downward to form a pivoting section, an inside of the pivoting section having a pivoting hole penetrating through a front surface of the pivoting section, an opening of the pivoting hole being corresponding to the mounting hole, one side of the top of the peripheral wall defining a penetrating hole vertically penetrating through the top of the peripheral wall; a push button structure assembled into the main shell through the mounting hole, the push button structure having a push button, a retaining flange extended outward and downward from the push button, a pivoting shaft extending longitudinally, a triggering element protruded downward from a bottom surface of the push button and a connecting arm, the pivoting shaft being rotatably inserted into the pivoting hole through the opening of the pivoting hole, the push button being movably disposed in the penetrating hole, the retaining flange abutting against the inner surface of the top of the peripheral wall of the main shell, two sides of the connecting arm being connected to the pivoting shaft and the retaining flange; an adapter unit assembled into the main shell through the mounting hole, the adapter unit having a switch unit mounted on a top surface of the adapter unit, the triggering element being disposed corresponding to the switch unit; a lid sealing the mounting hole, a middle of a front wall of the lid defining a connecting hole longitudinally penetrating through the front wall of the lid; and a connector fastened to a front end of the adapter unit, the connector being electrically connected to the adapter unit, the connector being mounted in the main shell, a front end of the connector projecting out of the connecting hole.

As described above, the wireless adapter includes the housing, the adapter unit received in the housing, the connector mounted in the housing to be electrically connected to the adapter unit, and the push button structure which has the assembling end and the moving end. An inner surface of the housing is provided with the pivoting section, the peripheral wall of the main shell of the housing defines the penetrating hole, the assembling end is cooperated with the pivoting section to be inserted into the pivoting hole of the pivoting section. Furthermore, the moving end has the push button movably disposed in the penetrating hole, the retaining flange extended outward and downward from the periphery of the push button, and the triggering element protruded downward from the bottom surface of the push button and connected with the two inner side surfaces of the retaining flange, the triggering element is disposed corresponding to the switch unit of the adapter unit. A thickness of the push button is no more than a depth of the penetrating hole, so a lateral space which is taken up by the wireless adapter is decreased to make the wireless adapter carried conveniently. In addition, a size of the push button is cooperated with a size of the penetrating hole, when the push button is pushed downward or is released, the push button is guided in the penetrating hole to move along the penetrating hole, and the retaining flange abuts against the inner surface of the top of the peripheral wall of the main shell, and the bottom wall of the penetrating hole is blocked by the retaining flange to prevent the push button structure breaking away from the housing so as to improve a stability of the push button structure. As a result, the wireless adapter is portable, and the wireless adapter has simple assembling procedures and improves the stability of the push button structure.

### BRIEF DESCRIPTION OF THE DRAWINGS

The present invention will be apparent to those skilled in the art by reading the following description, with reference to the attached drawings, in which:

FIG. 1 is a perspective view of a wireless adapter in accordance with the present invention;

FIG. 2 is an exploded view of the wireless adapter in accordance with the present invention;

FIG. 3 is another exploded view of the wireless adapter in accordance with the present invention;

FIG. 4 is a perspective view of a main shell of the wireless adapter in accordance with the present invention;

FIG. 5 is a perspective view of a push button structure of the wireless adapter in accordance with the present invention;

FIG. 6 is a cross-sectional view of the wireless adapter of FIG. 1; and

FIG. 7 is a partially cross-sectional view of the wireless adapter along a line VII-VII of FIG. 1.

### DETAILED DESCRIPTION OF THE INVENTION

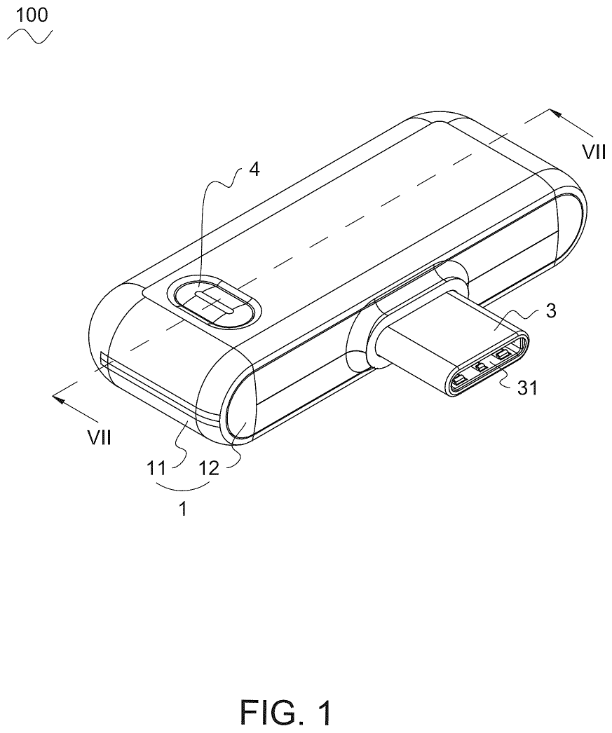

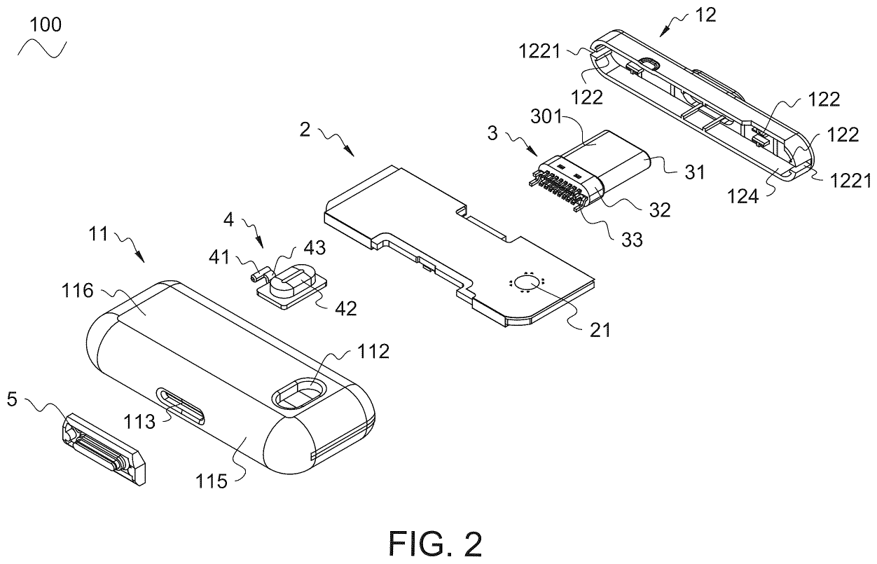

Referring to FIG. 1 and FIG. 2, a wireless adapter 100 in accordance with the present invention is shown. The wireless adapter 100 includes a housing 1, an adapter unit 2 mounted in the housing 1, a connector 3 disposed in the housing 1, a push button structure 4 and a light guiding unit 5 mounted in the housing 1. The connector 3 is electrically connected to the adapter unit 2.

Referring to FIG. 1 to FIG. 3, the adapter unit 2 includes a switch unit 21 mounted on a top surface of the adapter unit 2 for controlling an operating state of the wireless adapter 100, and an indicating light 22 for indicating an operating state of the wireless adapter 100. The push button structure 4 is corresponding to the switch unit 21. The push button structure 4 is mounted on the switch unit 21. The light guiding unit 5 is corresponding to the indicating light 22. The light guiding unit 5 is disposed to a middle of a rear of the adapter unit 2, and the indicating light 22 is in alignment with a middle of the light guiding unit 5 so as to provide a convenience for the user to control a working status of the wireless adapter 100 by pressing the push button structure 4 and show a connection status of the wireless adapter 100.

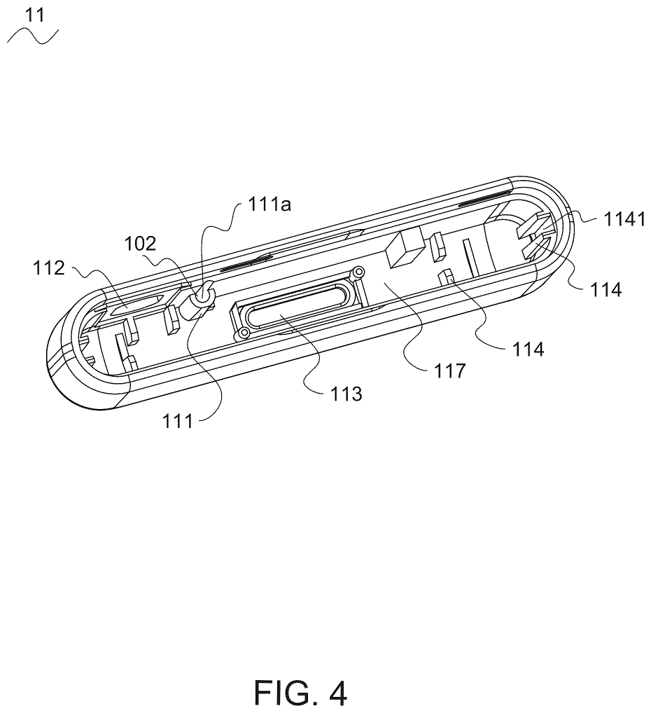

Referring to FIG. 2 to FIG. 4, the housing 1 includes a main shell 11 and a lid 12. The main shell 11 and the lid 12 are assembled with each other. The main shell 11 is shown as a hollow shape. A front end of the main shell 11 is opened freely. The lid 12 is covered to the front end of the main shell 11 to form a receiving space 101 between the main shell 11 and the lid 12. The main shell 11 and the lid 12 is combined by means of an adhesive dispensing way. The main shell 11 and the lid 12 together define the receiving space 101 for receiving the adapter unit 2, the connector 3, the push button structure 4 and the light guiding unit 5. The adapter unit 2 is received between the main shell 11 and the lid 12. The main shell 11 has a rear wall 115, and a peripheral wall 116 extended frontward form a periphery of the rear wall 115.

A front end of the peripheral wall 116 defines a mounting hole 117 communicated between an inside of the main shell 11 and an outside. The lid 12 seals the mounting hole 117 of the main shell 11 to define the receiving space 101 between the main shell 11 and the lid 12. An upper portion and a lower portion of each inner side surface of the peripheral wall 116 of the main shell 11 protrude inward to form two first buckling portions 114. The two first buckling portions 114 of each inner side surface of the peripheral wall 116 are disposed symmetrically. The two first buckling portions 114 of each inner side surface of the peripheral wall 116 are spaced to form a first clamping groove 1141 between the two first buckling portions 114. The two first clamping grooves 1141 of the two inner side surfaces of the peripheral wall 116 are matched with two rear ends of two sides of the adapter unit 2. The two rear ends of the two sides of the adapter unit 2 are assembled in the two first clamping grooves 1141 of the two inner side surfaces of the peripheral wall 116.

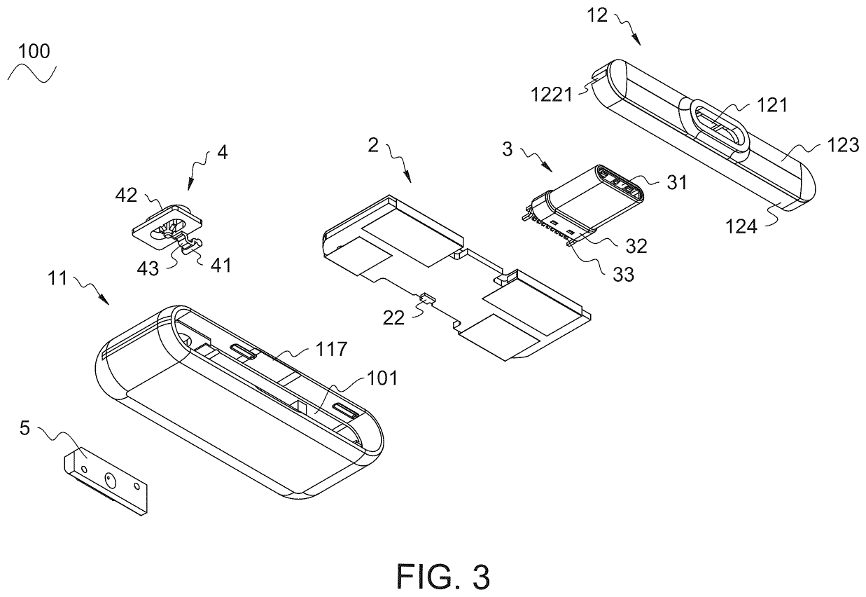

Referring to FIG. 2 and FIG. 3, the lid 12 has a front wall 123, and a mounting wall 124 extended rearward from a periphery of the front wall 123 of the lid 12. The lid 12 has a plurality of second buckling portions 122 protruded inward from an inner surface of the mounting wall 124 and an inner surface of the front wall 123 of the lid 12. Each two adjacent second buckling portions 122 are disposed symmetrically. Each two adjacent second buckling portions 122 are spaced from each other to form a second clamping groove 1221 between the two adjacent second buckling portions 122. Partial second clamping grooves 1221 of the plurality of the second buckling portions 122 penetrate through the mounting wall 124 of the lid 12. Specifically, the two second clamping grooves 1221 of two sides of the inner surface of the mounting wall 124 penetrate through two sides of the mounting wall 124. The two adjacent second buckling portions 122 of each side of the inner surface of the mounting wall 124 are aligned with the two first buckling portions 114 of one inner side surface of the peripheral wall 116 along a front-to-rear direction.

Two front ends of the two sides of the adapter unit 2 are matched with the two second clamping grooves 1221 of the two sides of the inner surface of the mounting wall 124. The two front ends of the two sides of the adapter unit 2 are assembled in the two second clamping grooves 1221 of the two sides of the inner surface of the mounting wall 124. Two second clamping grooves 1221 of two sides of the inner surface of the front wall 123 of the lid 12 are matched with two sides of a front end of the adapter unit 2. The two sides of the front end of the adapter unit 2 are assembled in the two second clamping grooves 1221 of the two sides of the inner surface of the front wall 123 of the lid 12. So the adapter unit 2 is clamped by the first buckling portions 114 of the peripheral wall 116 and the plurality of the second buckling portions 122, and the adapter unit 2 is fastened among the first buckling portions 114 of the peripheral wall 116 and the plurality of the second buckling portions 122. The adapter unit 2 is fastened in the receiving space 101.

Referring to FIG. 2 to FIG. 4, in order to facilitate an interaction between the user and the adapter unit 2 mounted in the housing 1, one side of a top of the peripheral wall 116 of the main shell 11 of the housing 1 defines a penetrating hole 112 vertically penetrating through the top of the peripheral wall 116 and corresponding to the switch unit 21, a middle of the rear wall 115 of the main shell 11 defines a light hole 113 longitudinally penetrating through the rear wall 115 and corresponding to the indicating light 22, and a middle of the front wall 123 of the lid 12 defines a connecting hole 121 longitudinally penetrating through the front wall 123 of the lid 12 and corresponding to the connector 3. A middle of a front end of the housing 1 defines the connecting hole 121 penetrating through a front surface of the housing 1. One side of a top of the housing 1 defines the penetrating hole 112 vertically penetrating through the top of the housing 1. The penetrating hole 112 is shown as a rounded rectangle shape. A middle of a rear of the housing 1 defines the light hole 113 longitudinally penetrating through the rear of the housing 1 and corresponding to the indicating light 22.

In order to increase a stability of the push button structure 4, one side of an inner surface of the top of the peripheral wall 116 of the housing 1 protrudes downward to form a pivoting section 111 assembled with the push button structure 4. One side of an inner surface of the top of the housing 1 protrudes downward to form the pivoting section 111. The pivoting section 111 is disposed adjacent to the penetrating hole 112. The pivoting section 111 is a tubular shape. The pivoting section 111 extends longitudinally. An inside of the pivoting section 111 has a pivoting hole 111a penetrating through a front surface of the pivoting section 111. An opening 102 of the pivoting hole 111a is corresponding to the mounting hole 117.

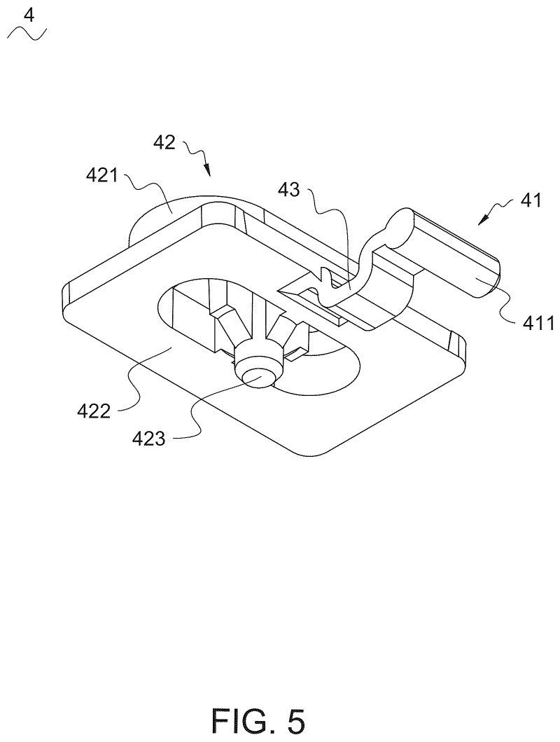

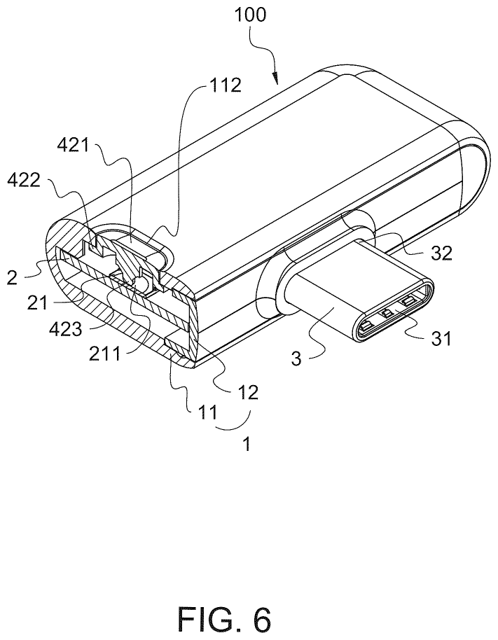

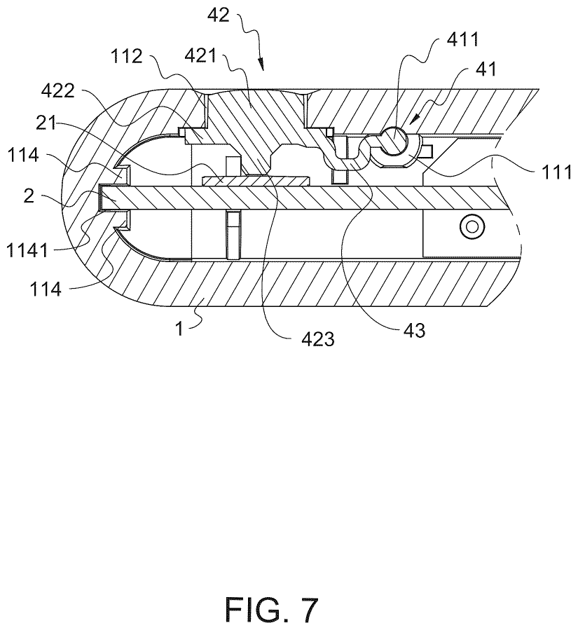

Referring to FIG. 5 to FIG. 7, the push button structure 4 has an assembling end 41, a moving end 42, and a connecting arm 43 connected between the assembling end 41 and the moving end 42. The assembling end 41 has a pivoting shaft 411 extending longitudinally. The push button structure 4 is received in the receiving space 101. The push button structure 4 is assembled into the main shell 11 through the mounting hole 117, the adapter unit 2 is assembled into the main shell 11 through the mounting hole 117, and the pivoting shaft 411 is rotatably inserted into the pivoting hole 111a of the pivoting section 111 through the opening 102 of the pivoting hole 111a, so that the pivoting section 111 of the main shell 11 is acted as a rotating center of the push button structure 4, the push button structure 4 rotates with respect to the main shell 11, and the push button structure 4 has a simple and convenient installation way.

The moving end 42 has a push button 421, a retaining flange 422 extended outward and downward from a periphery of the push button 421, and a triggering element 423 protruded downward from a bottom surface of the push button 421 and connected with two inner side surfaces of the retaining flange 422. The push button 421 is shown as another rounded rectangle shape. The retaining flange 422 is shown as a frame shape. The triggering element 423 is formed in a middle of the retaining flange 422. The triggering element 423 projects beyond a bottom surface of the retaining flange 422. The push button 421 is movably disposed in the penetrating hole 112 of the main shell 11. The retaining flange 422 abuts against the inner surface of the top of the housing 1. The retaining flange 422 abuts against the inner surface of the top of the peripheral wall 116 of the main shell 11, and a bottom wall of the penetrating hole 112 is blocked by the retaining flange 422. The triggering element 423 is disposed corresponding to the switch unit 21 of the adapter unit 2 for triggering the switch unit 21, and the triggering element 423 contacts with the switch unit 21 of the adapter unit 2 to trigger the switch unit 21. A top surface of the switch unit 21 has a resilient contacting point 211 which is able to be pressed. The triggering element 423 presses against the resilient contacting point 211 of the switch unit 21. The pivoting shaft 411 is abreast disposed opposite to the retaining flange 422.

A middle of the connecting arm 43 is a U shape. A mouth of the connecting arm 43 faces upward. Two free sides of the connecting arm 43 are transversely protruded oppositely from two sides of a top of the middle of the connecting arm 43. The two free sides of the connecting arm 43 are connected to the pivoting shaft 411 and the retaining flange 422. When the user presses downward on the push button 421, the connecting arm 43 pivots on the pivoting shaft 411 to rotate in a pressing direction of the push button 421, and the triggering element 423 presses downward on the resilient contacting point 211 of the switch unit 21 along the pressing direction of the push button 421 to activate the switch unit 21. When the user releases the push button 421, the resilient contacting point 211 of the switch unit 21 generates a resilient force to push the triggering element 423 to move upward, at the moment, the connecting arm 43 brings along the pivoting shaft 411 to rotate in a reverse direction which is opposite to the pressing direction of the push button 421 to make the connecting arm 43 rotate to an original position of the connecting arm 43, and the push button 421 is returned to an original position of the push button 421.

Referring to FIG. 1 to FIG. 7, the push button structure 4 is assembled to the housing 1 by inserting the pivoting shaft 411 into the pivoting hole 111a of the pivoting section 111, so an assembling procedure of the push button structure 4 and the housing 1 is simpler. The middle of the connecting arm 43 is shown as the U shape to be shorter so as to shorten a distance between the assembling end 41 and the moving end 42, so an occupied space of the push button structure 4 is saved. A thickness of the push button 421 is no more than a depth of the penetrating hole 112, so an overall thickness of the wireless adapter 100 is decreased.

Because a size of the push button 421 is cooperated with a size of the penetrating hole 112, and an outer diameter of the push button 421 fits an aperture diameter of the penetrating hole 112, when the push button 421 is pushed downward or is released, the push button 421 is guided in the penetrating hole 112 to move along the penetrating hole 112. The retaining flange 422 projects beyond a periphery of the penetrating hole 112. A size of the retaining flange 422 is larger than the aperture diameter of the penetrating hole 112 for preventing the push button structure 4 breaking away from the main shell 11, and the outer diameter of the push button 421 is slightly smaller than the aperture diameter of the penetrating hole 112 to prevent causing an interference between the push button 421 and an inner wall of the penetrating hole 112 at the time of the push button 421 being pressed.

Referring to FIG. 2 and FIG. 3, the indicating light 22 is mounted at a bottom surface of the adapter unit 2, and the indicating light 22 is disposed corresponding to the light guiding unit 5. The light guiding unit 5 is mounted in the light hole 113. A middle of a rear of the light guiding unit 5 is exposed to the light hole 113. An outer surface of the adapter unit 2 is affixed with an insulating layer. The insulating layer is an insulating tape. The connector 3 is fastened to a middle of the front end of the adapter unit 2. The connector 3 is mounted in the receiving space 101 of the main shell 1 of the housing 1. The connector 3 is disposed in the connecting hole 121. A front end of the connector 3 projects out of the connecting hole 121 of the housing 1. The connector 3 has a substantially hollow rectangular protecting shell 301 disposed at an outside of the connector 3. The connector 3 includes a connecting end 31 disposed at a front end of the connector 3, an assembling end 32 disposed at a middle of the connector 3, and a terminal module 33 exposed to a rear end of the connector 3. The terminal module 33 is received in the connector 3, and the terminal module 33 is exposed outside from a rear of the assembling end 32. The connecting end 31 is mate with a mating connector (not shown). The mating connector is docked with the connecting end 31 of the connector 3. The assembling end 32 and the terminal module 33 are assembled to the middle of the front end of the adapter unit 2. The assembling end 32 and the terminal module 33 are received in the receiving space 101 of the housing 1. The connecting end 31 projects out of the connecting hole 121 of the lid 12 of the housing 1. The terminal module 33 is electrically connected to the adapter unit 2.

As described above, the wireless adapter 100 includes the housing 1, the adapter unit 2 received in the housing 1, the connector 3 mounted in the housing 1 to be electrically connected to the adapter unit 2, and the push button structure 4 which has the assembling end 41 and the moving end 42. An inner surface of the housing 1 is provided with the pivoting section 111, the peripheral wall 116 of the main shell 11 of the housing 1 defines the penetrating hole 112, the assembling end 41 is cooperated with the pivoting section 111 to be inserted into the pivoting hole 111a of the pivoting section 111. Furthermore, the moving end 42 has the push button 421 movably disposed in the penetrating hole 112, the retaining flange 422 extended outward and downward from the periphery of the push button 421, and the triggering element 423 protruded downward from the bottom surface of the push button 421 and connected with the two inner side surfaces of the retaining flange 422, the triggering element 423 is disposed corresponding to the switch unit 21 of the adapter unit 2. The thickness of the push button 421 is no more than the depth of the penetrating hole 112, so a lateral space which is taken up by the wireless adapter 100 is decreased to make the wireless adapter 100 carried conveniently. In addition, the size of the push button 421 is cooperated with the size of the penetrating hole 112, when the push button 421 is pushed downward or is released, the push button 421 is guided in the penetrating hole 112 to move along the penetrating hole 112, and the retaining flange 422 abuts against the inner surface of the top of the peripheral wall 116 of the main shell 11, and the bottom wall of the penetrating hole 112 is blocked by the retaining flange 422 to prevent the push button structure 4 breaking away from the housing 1 so as to improve the stability of the push button structure 4. As a result, the wireless adapter 100 is portable, and the wireless adapter 100 has simple assembling procedures and improves the stability of the push button structure 4.

What is claimed is:

1. A wireless adapter, comprising: a housing, a front end of the housing defining a connecting hole penetrating through a front surface of the housing, one side of a top of the housing defining a penetrating hole vertically penetrating through the top of the housing, one side of an inner surface of the top of the housing protruding downward to form a pivoting section, the pivoting section having a pivoting hole penetrating through a front surface of the pivoting section; an adapter unit mounted in the housing, the adapter unit including a switch unit mounted on a top surface of the adapter unit; a connector fastened to a front end of the adapter unit, the connector being electrically connected to the adapter unit, the connector being disposed in the housing, a front end of the connector projecting out of the connecting hole of the housing; and a push button structure mounted in the housing, the push button structure having an assembling end which has a pivoting shaft extending longitudinally, a moving end movably disposed in the penetrating hole, and a connecting arm connected between the assembling end and the moving end, the pivoting shaft being rotatably inserted into the pivoting hole, the moving end having a triggering element, the triggering element being disposed corresponding to the switch unit of the adapter unit for triggering the switch unit.

2. The wireless adapter as claimed in claim 1, wherein the moving end has a push button, a retaining flange extended outward and downward from a periphery of the push button, and the triggering element protruded downward from a bottom surface of the push button and connected with two inner side surfaces of the retaining flange, the push button is movably disposed in the penetrating hole, the retaining flange abuts against the inner surface of the top of the housing, and a bottom wall of the penetrating hole is blocked by the retaining flange, the triggering element projects beyond a bottom surface of the retaining flange, a middle of the connecting arm is shown as a U shape, a mouth of the connecting arm faces upward, two free sides of the connecting arm are transversely protruded oppositely from two sides of a top of the middle of the connecting arm, the two free sides of the connecting arm are connected to the pivoting shaft and the retaining flange.

3. The wireless adapter as claimed in claim 2, wherein a top surface of the switch unit has a resilient contacting point, the triggering element presses against the resilient contacting point of the switch unit, the triggering element contacts with the switch unit to trigger the switch unit.

4. The wireless adapter as claimed in claim 2, wherein a size of the retaining flange is larger than an aperture diameter of the penetrating hole.

5. The wireless adapter as claimed in claim 2, wherein a thickness of the push button is no more than a depth of the penetrating hole.

6. The wireless adapter as claimed in claim 1, wherein the housing includes a main shell and a lid which are assembled with each other, the main shell has a rear wall, and a peripheral wall extended frontward form a periphery of the rear wall, an upper portion and a lower portion of each inner side surface of the peripheral wall of the main shell protrude inward to form two first buckling portions, the two first buckling portions of each inner side surface of the peripheral wall are spaced to form a first clamping groove between the two first buckling portions, two rear ends of two sides of the adapter unit are assembled in the two first clamping grooves of the two inner side surfaces of the peripheral wall.

7. The wireless adapter as claimed in claim 6, wherein the lid has a front wall, and a mounting wall extended rearward from a periphery of the front wall, the lid has a plurality of second buckling portions protruded inward from an inner surface of the mounting wall and an inner surface of the front wall of the lid, each two adjacent second buckling portions are spaced from each other to form a second clamping groove between the two adjacent second buckling portions, two front ends of the two sides of the adapter unit are assembled in the two second clamping grooves of two sides of the inner surface of the mounting wall.

8. The wireless adapter as claimed in claim 7, wherein two sides of the front end of the adapter unit are assembled in the two second clamping grooves of two sides of the inner surface of the front wall of the lid, the adapter unit is fastened among the first buckling portions of the peripheral wall and the plurality of the second buckling portions.

9. The wireless adapter as claimed in claim 7, wherein the two adjacent second buckling portions of each side of the inner surface of the mounting wall are aligned with the two first buckling portions of one inner side surface of the peripheral wall along a front-to-rear direction.

10. The wireless adapter as claimed in claim 1, wherein the connector is disposed in the connecting hole, the connector includes a connecting end disposed at a front end of the connector, an assembling end disposed at a middle of the connector, and a terminal module exposed to a rear end of the connector, the terminal module is received in the connector, and the terminal module is exposed outside from a rear of the assembling end, the assembling end and the terminal module are assembled to a middle of the front end of the adapter unit, the assembling end and the terminal module are received in the housing, the connecting end projects out of the connecting hole, the terminal module is electrically connected to the adapter unit.

11. The wireless adapter as claimed in claim 1, wherein the adapter unit includes an indicating light, a middle of a rear of the housing defines a light hole longitudinally penetrating through the rear of the housing and corresponding to the indicating light, the wireless adapter includes a light guiding unit disposed to a middle of a rear of the adapter unit, the light guiding unit is corresponding to the indicating light, the light guiding unit is mounted in the light hole.

12. A wireless adapter, comprising: a main shell having a rear wall, and a peripheral wall extended frontward form a periphery of the rear wall, a front end of the peripheral wall defining a mounting hole communicated between an inside of the main shell and an outside, one side of an inner surface of a top of the peripheral wall protruding downward to form a pivoting section, an inside of the pivoting section having a pivoting hole penetrating through a front surface of the pivoting section, an opening of the pivoting hole being corresponding to the mounting hole, one side of the top of the peripheral wall defining a penetrating hole vertically penetrating through the top of the peripheral wall; a push button structure assembled into the main shell through the mounting hole, the push button structure having a push button, a retaining flange extended outward and downward from a periphery of the push button, a pivoting shaft extending longitudinally, a triggering element protruded downward from a bottom surface of the push button and connected with two inner side surfaces of the retaining flange, and a connecting arm, the pivoting shaft being disposed opposite to the retaining flange, the pivoting shaft being rotatably inserted into the pivoting hole through the opening of the pivoting hole, the push button being movably disposed in the penetrating hole, the retaining flange abutting against the inner surface of the top of the peripheral wall of the main shell, and a bottom wall of the penetrating hole being blocked by the retaining flange, a middle of the connecting arm being a U shape, two free sides of the connecting arm being transversely protruded oppositely from two sides of a top of the middle of the connecting arm, the two free sides of the connecting arm being connected to the pivoting shaft and the retaining flange; an adapter unit assembled into the main shell through the mounting hole, the adapter unit including a switch unit mounted on a top surface of the adapter unit, the triggering element being disposed corresponding to the switch unit; a lid sealing the mounting hole, a middle of a front wall of the lid defining a connecting hole longitudinally penetrating through the front wall of the lid; and a connector fastened to a front end of the adapter unit, the connector being electrically connected to the adapter unit, the connector being mounted in the main shell, a front end of the connector projecting out of the connecting hole.

13. A wireless adapter, comprising: a main shell having a peripheral wall, a front end of the peripheral wall defining a mounting hole communicated between an inside of the main shell and an outside, one side of an inner surface of a top of the peripheral wall protruding downward to form a pivoting section, an inside of the pivoting section having a pivoting hole penetrating through a front surface of the pivoting section, an opening of the pivoting hole being corresponding to the mounting hole, one side of the top of the peripheral wall defining a penetrating hole vertically penetrating through the top of the peripheral wall; a push button structure assembled into the main shell through the mounting hole, the push button structure having a push button, a retaining flange extended outward and downward from the push button, a pivoting shaft extending longitudinally, a triggering element protruded downward from a bottom surface of the push button and a connecting arm, the pivoting shaft being rotatably inserted into the pivoting hole through the opening of the pivoting hole, the push button being movably disposed in the penetrating hole, the retaining flange abutting against the inner surface of the top of the peripheral wall of the main shell, two sides of the connecting arm being connected to the pivoting shaft and the retaining flange; an adapter unit assembled into the main shell through the mounting hole, the adapter unit having a switch unit mounted on a top surface of the adapter unit, the triggering element being disposed corresponding to the switch unit; a lid sealing the mounting hole, a middle of a front wall of the lid defining a connecting hole longitudinally penetrating through the front wall of the lid; and a connector fastened to a front end of the adapter unit, the connector being electrically connected to the adapter unit, the connector being mounted in the main shell, a front end of the connector projecting out of the connecting hole.

14. The wireless adapter as claimed in claim 13, wherein a top surface of the switch unit has a resilient contacting point, the triggering element presses against the resilient contacting point of the switch unit, the triggering element contacts with the switch unit to trigger the switch unit.
